(19) United States
(12) Patent Application Publication
(10) Pub. No.: US 2006/0202225 A1
(43) Pub. Date: Sep. 14, 2006

(54) Submount for use in flipchip-structured light emitting device including transistor

(76) Inventors: Hyun Kyung Kim, Suwon (KR); Hyuk Min Lee, Seoul (KR); Hyoun Soo Shin, Seoul (KR); In Joon Pyeon, Seoul (KR)

Correspondence Address: LOWE HAUPTMAN BERNER, LLP, 1700 DIAGONAL ROAD, SUITE 300, ALEXANDRIA, VA, 22314, US

(21) Appl. No.: 11/430,999

(22) Filed: May 10, 2006

Related U.S. Application Data
(62) Division of application No. 10/998,941, filed on Nov. 30, 2004.

(30) Foreign Application Priority Data
Sep. 17, 2004 (KR) 2004-74657

(51) Int. Cl. H01L 33/00

(52) U.S. Cl. 257/99

(57) ABSTRACT

Disclosed herein is a submount to mount a light emitting diode in a flipchip-structured light emitting device. The submount including a transistor to mount a nitride semiconductor light emitting diode in a flipchip-structured light emitting device includes: a substrate made of a first conductive semiconductor material; a first region formed on a partial area of the substrate, and made of a second conductive semiconductor material; a second region formed on the remaining regions other than the first region, and made of the second conductive semiconductor material; first and second electrodes formed on the first and second regions, respectively; and a conductive layer formed on the back of the substrate, wherein the first and second electrodes are connected to an n-type electrode and a p-type electrode of the nitride semiconductor light emitting diode through the use of a bump.

### RELATED APPLICATIONS

The present application is based on, and claims priority from, Korean Application Number 2004-74657, filed Sep. 17, 2004, the disclosure of which is incorporated by reference herein in the entirety.

### BACKGROUND OF THE INVENTION

1. Field of the Invention

The present invention relates to a submount for use in a flipchip-structured light emitting device, and more particularly to a submount including a transistor for use in a flipchip-structured light emitting device using a nitride semiconductor light emitting diode, in which the submount for mounting the nitride semiconductor light emitting diode is manufactured as a transistor using a semiconductor material, so that it prevents a high-intensity current caused by static electricity from flowing into the nitride semiconductor light emitting diode without using an additional electronic element.

2. Description of the Related Art

In recent times, nitride semiconductors have been introduced, which use a nitride such as GaN, and have excellent physical and chemical characteristics so that they are increasingly popular as a core material of a photoelectric material or electronic element. Particularly, the nitride semiconductor light emitting diode is capable of emitting a variety of light wavelengths, for example, green light, blue light, and ultraviolet light. As individual brightness of the above-mentioned light wavelengths is rapidly increased due to the increasing development of associated technology, nitride semiconductor light emitting diodes have recently been applied to a variety of technical fields, for example, natural-colored electronic display boards and illumination systems, etc.

The above-mentioned nitride semiconductor light emitting diode is indicative of a light emitting diode for producing light having a blue or green wavelength, and is manufactured as a semiconductor material of the formula AlₓIn_{y}Ga_{(1-x-y)}N (where 0≦x≦1, 0≦y≦1, and 0≦x+y≦1). A nitride semiconductor crystal is grown on a nitride single-crystal substrate such as a sapphire substrate in consideration of lattice matching. The sapphire substrate is indicative of an electrically insulative substrate, so that a p-type electrode and an n-type electrode are formed on the same surface of the final nitride semiconductor light emitting diode.

Due to the above-mentioned structural characteristics, the nitride semiconductor light emitting diode is being intensively developed to be suitable for a flipchip structure. A flipchip-structured light emitting device including a conventional nitride semiconductor light emitting diode is shown in FIG. 1.

The flipchip-structured light emitting device 10 shown in FIG. 1 includes a nitride semiconductor light emitting diode positioned on a submount 111. The nitride semiconductor light emitting diode includes a sapphire substrate 11, an n-type nitride semiconductor layer 12 deposited on the sapphire substrate 11, an active layer 13 deposited on the n-type nitride semiconductor layer 12, and a p-type nitride semiconductor layer 14 deposited on the active layer 13. The nitride semiconductor light emitting diode welds individual electrodes 19a and 19b to individual lead patterns 112a and 112b deposited on the submount substrate 111 through the use of a conductive bump 81. The sapphire substrate 11 for use in the above-mentioned flipchip-structured light emitting device 10 is made of a transparent material, so that it is capable of being adapted as a light emitting surface.

As shown in FIG. 1, an electrode of the flipchip-structured nitride semiconductor light emitting diode, specifically, a p-type electrode must form an ohmic contact with a p-type nitride semiconductor layer 14, and must have a high reflection factor capable of reflecting the light emitted from the active layer 13 toward a light emitting surface. Therefore, the p-type electrode may further deposit an ohmic contact layer 15 having a high reflection factor on a p-type nitride semiconductor layer 14, as shown in FIG. 1.

The nitride semiconductor light emitting diode for use in the above-mentioned flip-chip structured light emitting device has a disadvantage in that it has very weak resistance to static electricity as compared to other compound semiconductors such as GaP or GaAlAs. Typically, a nitride semiconductor light emitting device may be destroyed by a forward constant voltage of several hundreds of volts (e.g., 100V), and may also be destroyed by a reverse constant voltage of several tens of volts (e.g., 30V). Nitride semiconductor light emitting diodes are very vulnerable to the above-mentioned constant-voltages and may be destroyed thereby.

In conclusion, there must be developed an improved technique capable of preventing the breakdown of a nitride semiconductor light emitting diode by blocking high-intensity static electricity from being applied to the nitride semiconductor light emitting diode.

### SUMMARY OF THE INVENTION

Therefore, the present invention has been made in view of the above problems, and it is an object of the invention to provide a submount including a transistor for use in a flipchip-structured light emitting device using a nitride semiconductor light emitting diode, in which the submount for mounting the nitride semiconductor light emitting diode is manufactured as a transistor including a semiconductor material, so that it prevents a high-intensity current caused by static electricity from flowing into the nitride semiconductor light emitting diode without using an additional electronic element.

In accordance with one aspect of the present invention, these objects are accomplished by providing a submount including a transistor to mount a nitride semiconductor light emitting diode in a flipchip-structured light emitting device, comprising: a substrate made of a first conductive semiconductor material; a first region formed on a partial area of the substrate, and made of a second conductive semiconductor material; a second region formed on the remaining regions other than the first region, and made of the second conductive semiconductor material; first and second electrodes formed on the first and second regions, respectively; and a conductive layer formed on the back of the substrate, wherein the first and second electrodes are connected to an n-type electrode and a p-type electrode of the nitride semiconductor light emitting diode.

Preferably, the first and second conductive semiconductor materials may be indicative of silicon (Si). Preferably, the nitride semiconductor light emitting diode may be connected to an external circuit via the first and second electrodes.

In accordance with another aspect of the present invention, there is provided a submount including a transistor to mount a nitride semiconductor light emitting diode in a flipchip-structured light emitting device, comprising: a substrate made of a first conductive semiconductor material; a first region formed on a partial area of the substrate, and made of a second conductive semiconductor material; a second region formed in the first region, and made of the second conductive semiconductor material; first and second electrodes formed on the substrate and the second region, respectively; and a conductive layer formed on the back of the substrate, wherein the first and second electrodes are connected to an n-type electrode and a p-type electrode of the nitride semiconductor light emitting diode.

Preferably, the first and second conductive semiconductor materials may be indicative of silicon (Si). Preferably, the nitride semiconductor light emitting diode may be connected to an external circuit via the second electrode and the conductive layer.

### BRIEF DESCRIPTION OF THE DRAWINGS

The above objects, and other features and advantages of the present invention will become more apparent after reading the following detailed description when taken in conjunction with the drawings, in which:

FIG. 1 is a cross-sectional view illustrating a conventional flipchip-structured light emitting device;

FIG. 2 is a cross-sectional view illustrating a submount including a transistor and a nitride semiconductor light emitting diode placed on the submount in accordance with a preferred embodiment of the present invention;

FIG. 3 is a circuit diagram illustrating the connection relationship between the nitride semiconductor light emitting diode and the submount including the transistor of FIG. 2 in accordance with a preferred embodiment of the present invention;

FIG. 4 is a cross-sectional view illustrating a submount including a transistor and a nitride semiconductor light emitting diode placed on the submount in accordance with another preferred embodiment of the present invention; and

FIG. 5 is a circuit diagram illustrating the connection relationship between the nitride semiconductor light emitting diode and the submount including the transistor of FIG. 4 in accordance with another preferred embodiment of the present invention.

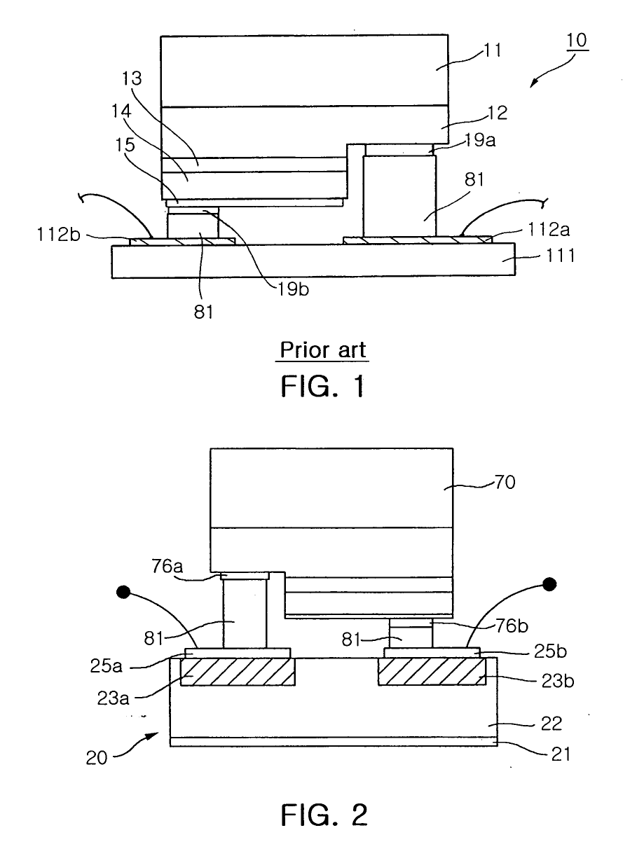

### DESCRIPTION OF THE PREFERRED EMBODIMENTS

Now, preferred embodiments of the present invention will be described in detail with reference to the annexed drawings. In the drawings, the same or similar elements are denoted by the same reference numerals even though they are depicted in different drawings. In the following description, a detailed description of known functions and configurations incorporated herein will be omitted when it may make the subject matter of the present invention rather unclear.

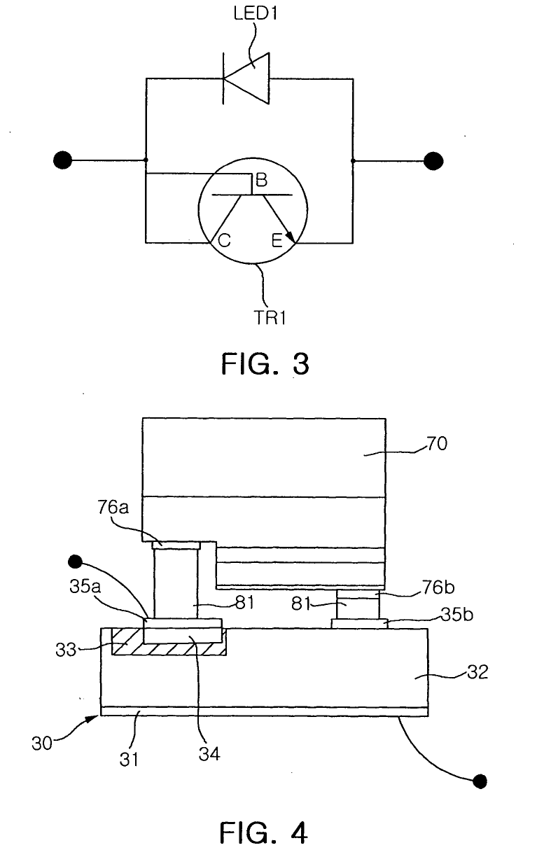

FIG. 2 is a cross-sectional view illustrating a submount including a transistor and a nitride semiconductor light emitting diode placed on the submount in accordance with a preferred embodiment of the present invention. Referring to FIG. 3, the submount 20 in accordance with a preferred embodiment of the present invention includes a substrate 22 made of a first conductive semiconductor material; a first region 23a formed on a partial area of the substrate 22, and made of a second conductive semiconductor material; a second region 23b formed on the remaining regions other than the first region 23a, and made of the second conductive semiconductor material; first and second electrodes 25a and 25b formed on the first and second regions 23a and 23b, respectively; and a conductive layer 21 formed on the back of the substrate 22. The above-mentioned submount 20 can be adapted to a flipchip-structured light emitting device. An n-type electrode 76a and a p-type electrode 76b of the nitride light emitting diode 70 in a flipchip structure can be connected to the first and second electrodes 25a and 25b using a conductive bump 81.

The substrate 22 is made of the first conductive semiconductor material. A representative example of the first conductive semiconductor material is silicon (Si). The substrate 22, the first region 23a, and the second region 23b are doped so as to have different conductivity types. For example, if the substrate 22 is made of a p-type doped semiconductor material, the first and second regions 23a and 23b are each made of an n-type doped material. In this case, the submount forms an npn-type transistor. Otherwise, if the substrate 22 is made of an n-type doped semiconductor material, the first and second regions 23a and 23b are each made of a p-type doped material. In this case, the submount forms a pnp-type transistor.

The first region 23a and the second region 23b can be formed by selectively implanting a dopant ion into a corresponding region of the substrate 22. For example, if the substrate 22 is a p-type doped substrate, an n-type dopant ion is implanted into the first and second regions 23a and 23b so that the first and second regions 23a and 23b are made of an n-type semiconductor material. Otherwise, if the substrate 22 is an n-type doped substrate, a p-type dopant ion is implanted into the first and second regions 23a and 23b so that the first and second regions 23a and 23b are made of a p-type semiconductor material.

The first electrode 25a, the second electrode 25b, and the conductive layer 21 are used as terminals of a transistor formed on the submount. For example, in the case of forming an npn-type transistor in which the substrate 22 is doped with a p-type semiconductor material and the first and second regions 23a and 23b are doped with an n-type semiconductor material, the first electrode 25a can be used as a collector terminal, and the second electrode 25b can be used as an emitter terminal, and the conductive layer 21 can be used as a base terminal. In this case, in order to prevent static electricity from being generated, the first electrode 25a acting as a collector terminal must be connected to an n-type electrode of the nitride semiconductor light emitting diode, and the second electrode 25b acting as an emitter terminal must be connected to a p-type electrode of the nitride semiconductor light emitting diode. The conductive layer 21 acting as a base terminal can be connected to the collector terminal.

The first electrode 25a and the second electrode 25b are connected to an external circuit through the use of wire bonding. The above-mentioned connection structure can provide a parallel connection between the nitride semiconductor light emitting diode and the transistor formed on the submount, as shown in FIG. 3.

FIG. 3 is a circuit diagram illustrating the connection relationship between the nitride semiconductor light emitting diode and the submount including the transistor of FIG. 2. Preferably, as shown in FIG. 3, if the transistor formed on the submount is determined to be an npn-type transistor, a cathode (i.e., n-type electrode) of a nitride semiconductor light emitting diode (LED1) is connected to a collector terminal of a transistor formed on a lower submount, and an anode (i.e., a p-type electrode) of the nitride semiconductor light emitting diode (LED1) is connected to an emitter terminal of the transistor formed on the lower submount.

The circuit diagram of FIG. 3 shows an example, in which a substrate of a submount is doped with a p-type semiconductor material, and the first and second regions are each doped with an n-type semiconductor material, so that an npn-type transistor is formed. Preferably, if the transistor formed on the submount is determined to be a pnp-type transistor, a cathode (i.e., an n-type electrode) of the nitride semiconductor light emitting diode (LED1) is connected to the emitter terminal of the transistor formed on the lower submount, and an anode (i.e., a p-type electrode) of the nitride semiconductor light emitting diode (LED1) is connected to the collector terminal of the transistor formed on the lower submount.

Operations of the circuit shown in FIG. 3 will hereinafter be described. If a forward voltage is applied to both terminals of the nitride semiconductor light emitting diode (LED1), a reverse voltage is applied to the transistor TR1. A breakdown voltage of such a transistor is about −10V, so that a current flows in the nitride semiconductor light emitting diode (LED1) if a forward voltage applied to the nitride semiconductor light emitting diode (LED1) is less than 10V. In more detail, the current flows in the nitride semiconductor light emitting diode (LED1) only when the forward voltage of the nitride semiconductor light emitting diode (LED1) is equal to or less than 10V. If a voltage higher than 10V is applied to the nitride semiconductor light emitting diode (LED1), a current flows in the transistor TR1, resulting in a guarantee of security in regard to forward static electricity of more than 10V.

Also, if a reverse voltage is applied to the nitride semiconductor light emitting diode (LED1), this means that a forward voltage is applied to the transistor TR1, so that the transistor TR1 is operated at about 3.5V. Therefore, if a reverse voltage of more than about 3.5V is applied to the nitride semiconductor light emitting diode (LED1), a current flows in the transistor TR1, resulting in a guarantee of security in regard to reverse static electricity of more than 3.5V.

As described above, a forward breakdown voltage of the nitride semiconductor light emitting diode (LED1) is determined to be about 100V, and a reverse breakdown voltage thereof is determined to be about 30V, so that the breakdown of the nitride semiconductor light emitting diode (LED1) due to a high voltage such as static electricity can be prevented.

FIG. 4 is a cross-sectional view illustrating a submount including a transistor and a nitride semiconductor light emitting diode placed on the submount in accordance with another preferred embodiment of the present invention. Referring to FIG. 4, the submount 30 in accordance with another preferred embodiment of the present invention includes a substrate 32 made of a first conductive semiconductor material; a first region 33 formed on a partial area of the substrate 32, and made of a second conductive semiconductor material; a second region 34 formed in the first region 33, and made of the second conductive semiconductor material; first and second electrodes 35a and 35b formed on the substrate 32 and the second region 34, respectively; and a conductive layer 31 formed on the back of the substrate 32. The above-mentioned submount 30 can be adapted to a flipchip-structured light emitting device. An n-type electrode 76a and a p-type electrode 76b of the nitride light emitting diode 70 in a flipchip structure can be connected to the first and second electrodes 35a and 35b using a conductive bump 81.

Differently from the submount shown in FIG. 2, the submount shown in FIG. 4 includes the second region 34 having a conductivity type equal to that of the substrate 32 in the first region 33 having another conductivity type different from that of the substrate 32. The above-mentioned difference is generated by a difference between transistor implementation methods. Operations of the submount of FIG. 4 are basically equal to those of the submount of FIG. 2. However, the substrate 32 and the first and second regions 33 and 34 have different configurations as compared to those of FIG. 2, so that the second electrode 34 is connected to a light emitting diode or is connected to an external device via the conductive layer 31 according to a wire bonding method.

The substrate 32 is made of the first conductive semiconductor material. A representative example of the first conductive semiconductor material is silicon (Si). The substrate 32 and the first region 33 are doped so as to have different conductivity types, and the second region 34 is doped so as to have the same conductivity type as the substrate 32. For example, if the substrate 32 is made of a p-type doped semiconductor material, the first region 33 is made of an n-type doped material, and the second region 23 is made of a p-type doped material. In this case, the submount forms a pnp-type transistor. Otherwise, if the substrate 32 is made of an n-type doped semiconductor material, the first and second regions 33 and 34 are made of the p-type doped material and the n-type doped material, respectively. In this case, the submount forms an npn-type transistor.

The first region 33 can be formed by selectively implanting a dopant ion into a corresponding region of the substrate 32. For example, if the substrate 32 is a p-type doped substrate, an n-type dopant ion is implanted into the first region 33 so that the first region 33 is made of the n-type semiconductor material. Thereafter, a p-type dopant ion is implanted into a part of the first region 33 so that the second region 34 is made of a p-type semiconductor material.

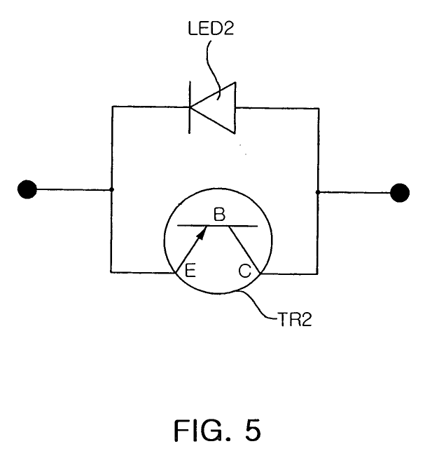

The first electrode 35a, the second electrode 35b, and the conductive layer 31 are used as terminals of a transistor formed on the submount. For example, in the case of forming a pnp-type transistor in which the substrate 32 is doped with a p-type semiconductor material and the first and second regions 33 and 34 are doped with an n-type semiconductor material and a p-type semiconductor material, respectively, the first electrode 35a can be used as an emitter terminal and the conductive layer 31 can be used as a collector terminal. In this example, the base terminal can be omitted. In this case, in order to prevent static electricity from being generated, the first electrode 35a acting as an emitter terminal must be connected to an n-type electrode of the nitride semiconductor light emitting diode, and the conductive layer acting as a collector terminal must be connected to a p-type electrode of the nitride semiconductor light emitting diode. In FIG. 4, the conductive layer 31 is substantially connected to the p-type electrode 76b of the nitride semiconductor light emitting diode 90 via the substrate 32 and the second electrode 35b. The first electrode 35a and the conductive layer 31 are connected to an external circuit through the use of wire bonding. The above-mentioned connection structure can provide a parallel connection between the nitride semiconductor light emitting diode and the transistor formed on the submount, as shown in FIG. 5.

FIG. 5 is a circuit diagram illustrating the connection relationship between the nitride semiconductor light emitting diode and the submount including the transistor of FIG. 4. Preferably, as shown in FIG. 5, if the transistor formed on the submount is determined to be a pnp-type transistor, a cathode (i.e., n-type electrode) of a nitride semiconductor light emitting diode (LED1) is connected to an emitter terminal of a transistor formed on a lower submount, and an anode (i.e., a p-type electrode) of the nitride semiconductor light emitting diode (LED1) is connected to a collector terminal of the transistor formed on the lower submount.

The circuit diagram of FIG. 5 shows an example, in which a substrate of a submount is doped with the p-type semiconductor material, and the first and second regions are doped with the n-type semiconductor material and the p-type semiconductor material, respectively, so that a pnp-type transistor is formed. Preferably, if the transistor formed on the submount is determined to be an npn-type transistor, a cathode (i.e., an n-type electrode) of the nitride semiconductor light emitting diode (LED2) is connected to the collector terminal of the transistor formed on the lower submount, and an anode (i.e., a p-type electrode) of the nitride semiconductor light emitting diode (LED2) is connected to the emitter terminal of the transistor formed on the lower submount.

Operations of the circuit shown in FIG. 5 will hereinafter be described. If a forward voltage is applied to both terminals of the nitride semiconductor light emitting diode (LED2), a reverse voltage is applied to the transistor TR2. A breakdown voltage of such a transistor is generally about −10V, so that a current flows in the nitride semiconductor light emitting diode (LED2) if a forward voltage applied to the nitride semiconductor light emitting diode (LED2) is less than 10V. In more detail, the current flows in the nitride semiconductor light emitting diode (LED2) only when the forward voltage of the nitride semiconductor light emitting diode (LED2) is equal to or less than 10V. If a voltage higher than 10V is applied to the nitride semiconductor light emitting diode (LED2), a current flows in the transistor TR2, resulting in a guarantee of security in regard to forward static electricity of more than 10V.

Also, if a reverse voltage is applied to the nitride semiconductor light emitting diode (LED2), this means that a forward voltage is applied to the transistor TR2, so that the transistor TR2 is operated at about 3.5V. Therefore, if a reverse voltage of more than about 3.5V is applied to the nitride semiconductor light emitting diode (LED2), a current flows in the transistor TR2, resulting in a guarantee of security in regard to reverse static electricity of more than 3.5V.

As described above, a forward breakdown voltage of the nitride semiconductor light emitting diode (LED2) is determined to be about 100V, and a reverse breakdown voltage thereof is determined to be about 30V, so that the breakdown of the nitride semiconductor light emitting diode (LED2) due to a high voltage such as static electricity can be prevented.

In accordance with the above-described present invention, although a light emitting diode and a transistor are connected in parallel to each other, the light emitting diode can also be connected in parallel to a diode such as a zener diode, instead of the transistor, such that the parallel connection between the light emitting diode and the diode prevents static electricity from being generated. In more detail, the light emitting diode and the diode are connected to two terminals in order to be assigned different polarities, so that a current caused by a reverse voltage applied to the light emitting diode flows in the diode connected in a forward direction, resulting in the creation of a means for preventing static electricity. However, the diode such as a zener diode has a leakage current higher than that of the transistor and a breakdown voltage less than that of the transistor. Therefore, a current applied to the light emitting diode is reduced due to the leakage current so that the light emitting diode may be incorrectly operated, or a current to be applied to the light emitting diode may incorrectly flow in a diode in a breakdown state due to a low breakdown voltage. Therefore, it is preferable for the transistor to be used for the blocking of static electricity, instead of using the diode.

As apparent from the above description, the present invention provides a submount for use in a flipchip-structured light emitting device using a nitride semiconductor light emitting diode, in which the submount for mounting the nitride semiconductor light emitting diode is manufactured as a transistor using a semiconductor material, so that it prevents a high-intensity current caused by static electricity from flowing into the nitride semiconductor light emitting diode without using an additional electronic element, so that it prevents the breakdown of the nitride semiconductor light and increases reliability of the same.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

1-3. (canceled)

4. A submount to mount a nitride semiconductor light emitting diode in a flipchip-structured light emitting device, comprising:
a substrate made of a first conductive semiconductor material;
a first region formed on a partial area of the substrate, and made of a second conductive semiconductor material;
a second region formed in the first region, and made of the second conductive semiconductor material;
first and second electrodes formed on the substrate and the second region, respectively; and
a conductive layer formed on the back of the substrate,
wherein the first and second electrodes are connected to an n-type electrode and a p-type electrode of the nitride semiconductor light emitting diode.

5. The submount according to claim 4, wherein the first and second conductive semiconductor materials are indicative of silicon (Si).

6. The submount according to claim 4, wherein the nitride semiconductor light emitting diode is connected to an external circuit via the second electrode and the conductive layer.
